(19) United States
(12) Patent Application Publication
(10) Pub. No.: US 2010/0224128 A1
(43) Pub. Date: Sep. 9, 2010

(54) SEMICONDUCTOR MANUFACTURING APPARATUS

(75) Inventors: Takatomo YAMAGUCHI, Toyama-shi (JP); Kenji SHIRAKO, Toyama-shi (JP); Hiroaki HIRAMATSU, Toyama-shi (JP)

Correspondence Address: BRUNDIDGE & STANGER, P.C., 2318 MILL ROAD, SUITE 1020, ALEXANDRIA, VA, 22314, US

(73) Assignee: HITACHI-KOKUSAI ELECTRIC INC., Tokyo (JP)

(21) Appl. No.: 12/717,420

(22) Filed: Mar. 4, 2010

(30) Foreign Application Priority Data
Mar. 9, 2009 (JP) 2009-054384

(51) Int. Cl. C23C 16/00; H01L 21/02

(52) U.S. Cl. 118/720; 118/723 R

(57) ABSTRACT

Provided is a semiconductor manufacturing apparatus in which the density of plasma generating in a reaction chamber can be uniformly maintained. The semiconductor manufacturing apparatus comprises a process chamber configured to process a substrate, a plurality of electrodes installed outside the process chamber for generating plasma, and an adjusting unit disposed between the process chamber and the electrodes for adjusting density of plasma generating in the process chamber.

### CROSS-REFERENCE TO RELATED PATENT APPLICATION

This U.S. non-provisional patent application claims priority under 35 U.S.C. §119 of Japanese Patent Application No. 2009-054384, filed on Mar. 9, 2009, in the Japanese Patent Office, the entire contents of which are hereby incorporated by reference.

### BACKGROUND OF THE INVENTION

1. Field of the Invention

The present invention relates to a semiconductor manufacturing apparatus.

2. Description of the Prior Art

Generally, the density of capacity coupled plasma (CCP), about 10¹⁰ cm⁻³ (˜10¹⁰ cm³), is lower than the density of inductively coupled plasma (ICP), about 10¹² cm⁻³ (˜10¹² cm⁻³). In addition, since the density uniformity of CCP cannot be adjusted in the vertical direction of a substrate, the flowrate of gas or the process temperature is adjusted for obtaining desired thickness uniformity of a film formed on the substrate. However, this varies the quality of films and becomes one of yield reducing factors.

In a vertical semiconductor manufacturing apparatus, a plasma excitation method using CCP is disadvantageous because plasma density is low as compared with those obtained by using other methods and it is difficult to improve the manufacturing yield. In the case of CCP, ions of plasma that have a high temperature and high energy may collide with a quartz wall or a film formed on the quartz wall so that the quartz wall or the film may be damaged by sputtering. If high-frequency power is increased to generate high-density plasma, plasma density (ion density) increases at a region close to a quartz wall of a reaction chamber, and thus the possibility of sputtering of the quartz wall of the reaction chamber increases.

Moreover, there is no permanent magnet that can resist temperature conditions of a film forming process, and magnets cannot be installed in a vertical type heater. Therefore, a device such as an electron cyclotron resonance (ECR) plasma source that uses magnets cannot be used in a vertical semiconductor manufacturing apparatus.

Due to above-mentioned reasons, ICP sources that can produce high-density plasma and have a simple structure are suitable for a vertical semiconductor manufacturing apparatus. However, in the case of an ICP source, as the length of a radio frequency (RF) antenna increases, the voltage difference between both ends of the RF antenna increases. If a high voltage is applied to an RF antenna, CCP is generated between parts of the RF antenna or between the RF antenna and an earthed part (a lower metal part of a vertical apparatus). Such CCP incurs an RF power loss.

To deal with this problem, a plurality of RF antennas are installed.

In a plasma processing apparatus disclosed in Patent Document 1 below, a plurality of lines of antennas are installed, and the impedance of each bus bar section and the impedance of each power supply line are adjusted so that the same voltage can be applied to the antennas. In this way, uniform high-frequency power is supplied to the antennas to generate ICP.

[Patent Document 1]

Japanese Unexamined Patent Application Publication No. 2007-220594

However, in the conventional art, the density of plasma generated in a reaction chamber cannot be made uniform.

### SUMMARY OF THE INVENTION

An object of the present invention is to provide a semiconductor manufacturing apparatus in which the density of plasma generating in a reaction chamber can be uniformly maintained.

According to an aspect of the present invention, there is provided a semiconductor manufacturing apparatus comprising: a process chamber configured to process a substrate; a plurality of electrodes installed outside the process chamber for generating plasma; and an adjusting unit disposed between the process chamber and the electrodes for adjusting density of plasma generating in the process chamber.

### BRIEF DESCRIPTION OF THE DRAWINGS

FIG. 1 is a perspective view illustrating a semiconductor manufacturing apparatus according to an embodiment of the present invention.

FIG. 2 is a side sectional view illustrating a process furnace of the semiconductor manufacturing apparatus according to an embodiment of the present invention.

FIG. 3 is a cross sectional view illustrating the process furnace of the semiconductor manufacturing apparatus according to an embodiment of the present invention.

FIG. 4A and FIG. 4B are views illustrating the peripheral structure of high-frequency antennas of the semiconductor manufacturing apparatus according to an embodiment of the present invention, FIG. 4A being a schematic front view illustrating the high-frequency antennas, FIG. 4B being a side sectional view illustrating the peripheral structure of the high-frequency antennas.

FIG. 5A and FIG. 5B are views illustrating the peripheral structure of high-frequency antennas of a semiconductor manufacturing apparatus according to another embodiment of the present invention, FIG. 5A being a schematic front view illustrating the high-frequency antennas, FIG. 5B being a side sectional view illustrating the peripheral structure of the high-frequency antennas.

FIG. 6A and FIG. 6B are views illustrating the peripheral structure of high-frequency antennas of a semiconductor manufacturing apparatus according to another embodiment of the present invention, FIG. 6A being a schematic front view illustrating the high-frequency antennas, FIG. 6B being a side sectional view illustrating the peripheral structure of the high-frequency antennas.

### DETAILED DESCRIPTION OF THE PREFERRED EMBODIMENTS

### First Embodiment

Embodiments of the present invention will be described hereinafter with reference to the attached drawings.

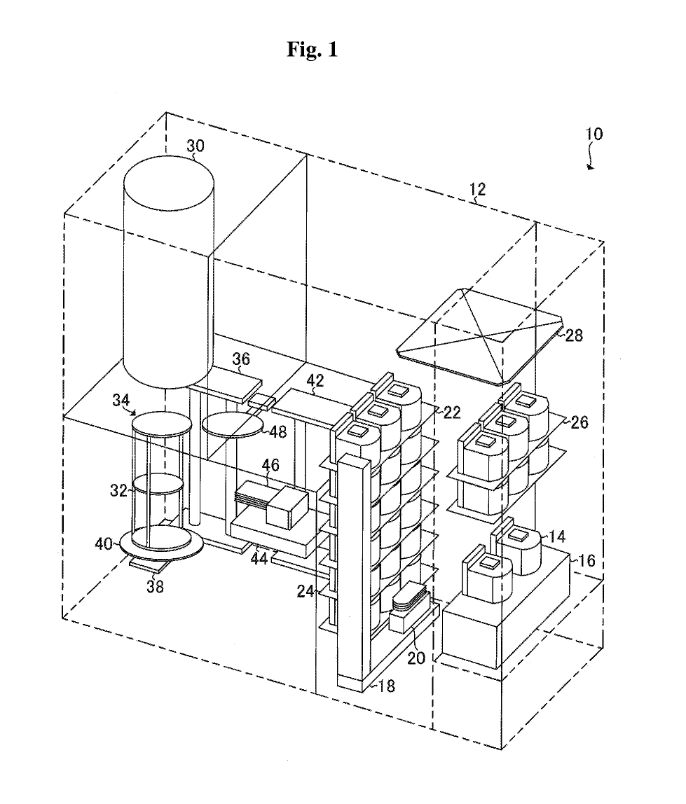

FIG. 1 is a perspective view illustrating a semiconductor manufacturing apparatus 10 according to an embodiment of the present invention. The semiconductor manufacturing apparatus 10 is a batch type vertical semiconductor manufacturing apparatus, and the semiconductor manufacturing apparatus 10 includes a case 12 in which main parts are disposed. At the front side of the case 12, a cassette stage 16 is installed as a substrate container stage member so that substrate containers such as cassettes 14 can be delivered between the cassette stage 16 and an external carrying device (not shown). At the rear side of the cassette stage 16, a cassette elevator 18 is installed as an elevating unit, and a transfer machine 20 is installed on the cassette elevator 18 as a carrying unit. In addition, at the rear side of the cassette elevator 18, a cassette shelf 22 is installed as a cassette placement unit. At the cassette shelf 22, a transfer shelf 24 is installed so that cassettes 14 can be accommodated on the transfer shelf 24 and carried by a wafer transfer machine 44 (described later). At the upper side of the cassette stage 16, a standby cassette shelf 26 is installed, and at the upper side of the standby cassette shelf 26, a cleaning unit 28 is installed to circulate clean air through the inside of the case 12.

At the rear upper part of the case 12, a process furnace 30 is installed. Under the process furnace 30, a boat 34 is installed as a substrate holding unit configured to hold substrates such as wafers 32 in a state where the wafers 32 are horizontally oriented and arranged in multiple stages, and a boat elevator 36 is installed as an elevating unit configured to move the boat 34 upward and downward with respect to the process furnace 30. At the leading end of an elevating member 38 installed on the boat elevator 36, a seal cap 40 is installed as a cover configured to support the boat 34 vertically. Between the boat elevator 36 and the cassette shelf 22, a transfer elevator 42 is installed as an elevating unit, and at the transfer elevator 42, the wafer transfer machine 44 is installed as a substrate carrying unit. The wafer transfer machine 44 includes an arm (tweezers) 46 capable of picking up, for example, five wafers 32. Near the boat elevator 36, a furnace port shutter 48 is installed as a shield member for closing the bottom side of the process furnace 30 having an opening/closing mechanism.

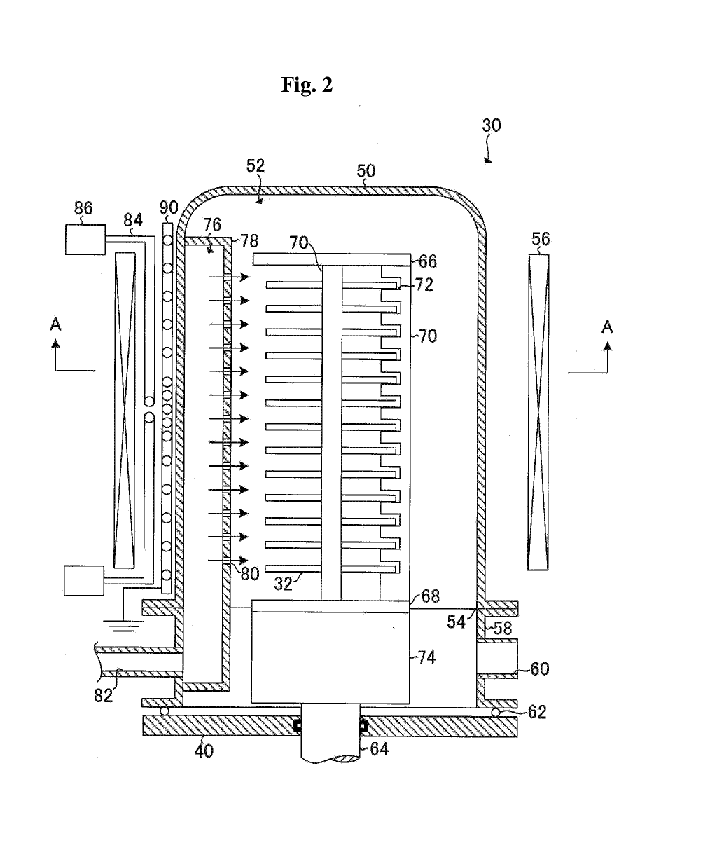

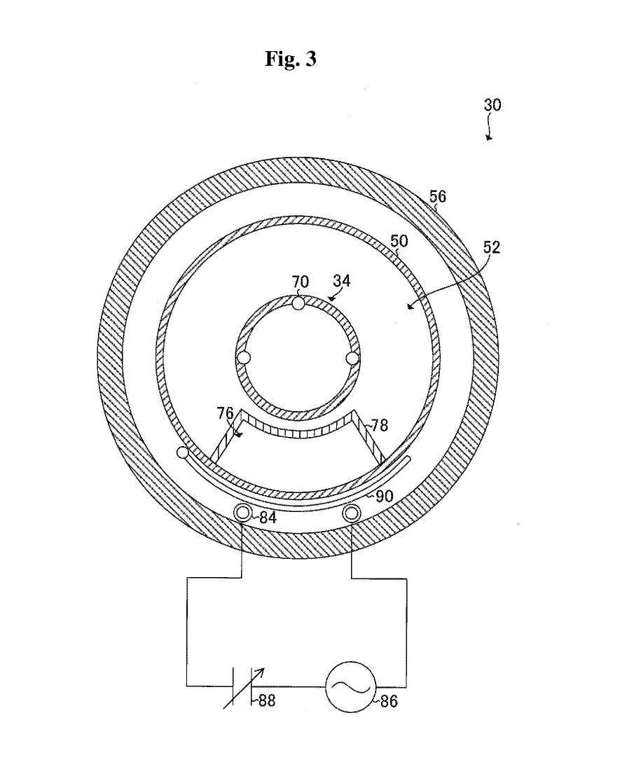

Next, the process furnace 30 will be described in detail with reference to FIG. 2 and FIG. 3.

FIG. 2 is a schematic view illustrating the vertical process furnace 30 according to an embodiment of the present invention, and FIG. 3 is a sectional view taken along line A-A of FIG. 2. The process furnace 30 includes a process tube 50, which is made of a highly heat resistant material such as quartz glass and has a cylindrical shape of which one end is opened and the other end is closed, and the process tube 50 is vertically disposed and fixedly supported so that the centerline of the process tube 50 can be vertical. At the hollow part of the process tube 50, a process chamber 52 is formed to accommodate the boat 34 holding a plurality of wafers 32, and the opened bottom side of the process tube 50 forms a furnace port 54 through which the boat 34 is loaded and unloaded. The inner diameter of the process tube 50 is set greater than the largest outer diameter of wafers 32 to be processed.

At the outside of the process tube 50, a heater 56 is installed to surround the process tube 50 and be coaxial with the process tube 50 so as to heat the entire region of the process chamber 52 uniformly, and the heater 56 is vertically fixed.

At the bottom side of the process tube 50, a manifold 58 is installed to make contact with the process tube 50, and the manifold 58 is made of a metal and has a cylindrical shape of which both ends extends outward as flanges. The manifold 58 is detachably attached to the process tube 50 for maintenance or cleaning works of the process tube 50.

An end of an exhaust pipe 60 is connected to a part of the sidewall of the manifold 58, and the other end of the exhaust pipe 60 is connected to an exhaust device (not shown), so that the process chamber 52 can be exhausted. The seal cap 40 is brought into contact with the bottom side of the manifold 58 in a vertical direction from the lower side of the manifold 58 with a seal ring 62 being disposed therebetween, so as to close the opened bottom side of the manifold 58. The seal cap 40 is disk-shaped and has approximately the same outer diameter as the outer diameter of the manifold 58, and the seal cap 40 is configured to be vertically moved by the boat elevator 36 (refer to FIG. 1). A rotation shaft 64 is inserted through the center of the seal cap 40 and is configured to be vertically moved together with the seal cap 40 and be rotated by a rotary driving device (not shown). On the top end of the rotation shaft 64, the boat 34 is vertically based and supported.

The boat 34 includes a pair of plates 66 and 68 at upper and lower sides, and holding members 70 (for example, three holding members 70) vertically installed between the plates 66 and 68. At each of the holding members 70, a plurality of holding grooves 72 are arranged at regular intervals in the longitudinal direction of the holding member 70 in a manner such that the holding grooves 72 of the holding members 70 face each other. In a way of inserting the edge parts of wafers 32 in the holding grooves 72 of the holding members 70, the wafers 32 can be held by the boat 34 in a state where the wafers 32 are horizontally oriented and vertically arranged with the centers of the wafers 32 being aligned with each other. At the bottom surface of the lower plate 66 of the boat 34, an insulating cap part 74 is formed, and the bottom surface of the insulating cap part 74 is supported on the rotation shaft 64.

At the inner surface of the process tube 50, a gutter-shaped barrier wall 78 is disposed to form a plasma chamber 76, and a plurality of injection holes 80 are arranged to face the wafers 32. A gas supply pipe 82 is installed at a lateral lower side of the process tube 50 to supply gas to the plasma chamber 76.

At a side opposite to the plasma chamber 76 located between the process tube 50 and the heater 56, high-frequency antennas 84 are vertically installed in two stages as plasma generating electrodes. At each of the high-frequency antennas 84, a high-frequency circuit matching unit 86 is installed so that the high-frequency antennas 84 can be individually matched. Plasma can be generated by applying high-frequency power to the high-frequency antennas 84 from high-frequency power sources 88, respectively.

In the current embodiment, high-frequency antennas 84 are installed in two stages; however, the present invention is not limited thereto. For example, a plurality of high-frequency antennas can be vertically installed in multiple stages for precisely controlling generation of plasma and the vertical density uniformity of the plasma.

A shield 90 is installed at the outer side of the process tube 50 between the high-frequency antennas 84 and the plasma chamber 76. When a high voltage is applied to the high-frequency antennas 84, the inner wall of the process tube 50 is negatively charged due to electrons accelerated by the high voltage, and ions are attracted to a static electric field formed by the negatively charged inner wall of the process tube 50, which causes atoms are sputtered from the inner wall of the process tube 50. Due to the sputtering of the inner wall of the process tube 50, impurities such as oxygen can be generated. To prevent this, the shield 90 is installed to block an electric field so that plasma cannot be affected by electric fields of the high-frequency antennas 84.

In this way, sputtering of the inner wall of the process tube 50 can be prevented.

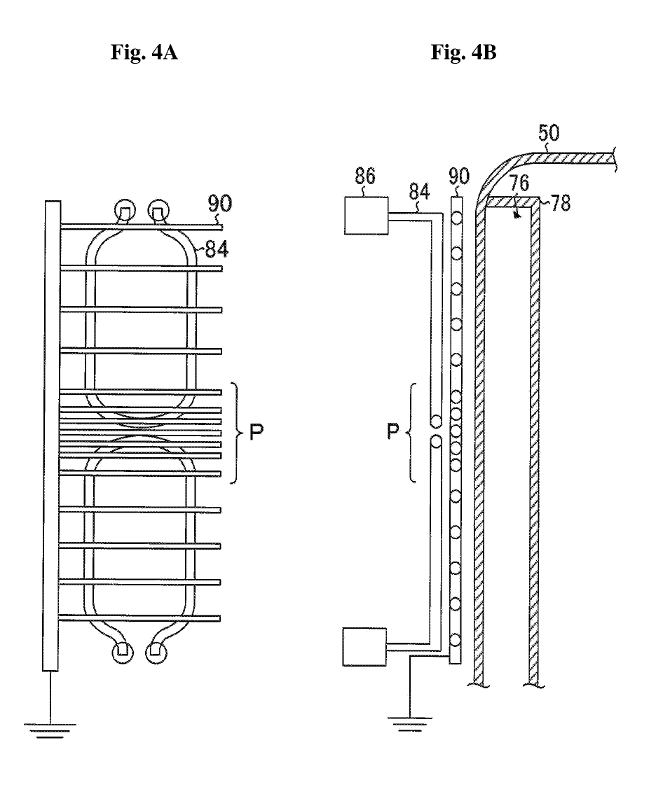

FIG. 4A and FIG. 4B illustrate the peripheral structures of the high-frequency antennas 84 and the shield 90. FIG. 4A is a schematic front view illustrating the high-frequency antennas 84, and FIG. 4B is a side view illustrating the peripheral structure of the high-frequency antennas 84. In the current embodiment, the shield 90 has a comb shape, and the teeth of the shield 90 are more densely arranged at an approach region (position P) between the two high-frequency antennas 84 as compared with the other part of the shield 90.

Next, an operation of the semiconductor manufacturing apparatus 10 will be explained.

A cassette 14 in which wafers 32 are charged is carried from the external carrying device (not shown) in a state where the wafers 32 charged in the cassette 14 face upward, and then the cassette 14 is placed on the cassette stage 16 in a manner such that the wafers 32 are horizontally oriented. The cassette 14 is carried from the cassette stage 16 to the cassette shelf 22 or the standby cassette shelf 26 by combination of elevating and transversely moving operations of the cassette elevator 18 and reciprocating and rotating operations of the transfer machine 20.

The cassette 14, in which the wafers 32 to be transferred to the process furnace 30 is accommodated, is carried to and accommodated on the transfer shelf 24 by the cassette elevator 18 and the transfer machine 20. After the cassette 14 is carried to the transfer shelf 24, wafers 32 are charged from the transfer shelf 24 to the boat 34 which is in a down position by combination of reciprocating and rotating operations of the wafer transfer machine 44 and elevating operations of the transfer elevator 42.

After a predetermined number of wafers 32 are charged into the boat 34, the boat 34 is inserted into the process furnace 30 by the boat elevator 36, and the seal cap 40 is closed so that the process furnace 30 can be hermetically closed.

After the boat 34 is loaded in the process chamber 52, the process chamber 52 is exhausted to a pressure equal to or lower than a predetermined value by the exhaust device connected to the exhaust pipe 60, and more power is supplied to the heater 56 to heat the process chamber 52 to a predetermined temperature. Since the heater 56 is hot-wall type, the inside temperature of the process chamber 52 can be uniformly maintained. Therefore, the temperature of the wafers 32 held in the boat 34 can be uniform along the entire length of the boat 34, and the in-surface temperature distribution of each of the wafers 32 can also be uniform.

After the process chamber 52 is heated to a predetermined temperature and stably kept at the predetermined temperature, a process gas is supplied through the gas supply pipe 82. When the pressure of the process chamber 52 reaches a preset pressure level, the boat 34 is rotated by the rotation shaft 64, and high-frequency power is applied to the high-frequency antennas 84 from the high-frequency power sources 88 through the high-frequency circuit matching units 86. Then, plasma is generated in the plasma chamber 76, and the process gas is activated into a reactive state.

Since an electric field is stronger at the approach region (position P) where the high-frequency antennas 84 approach each other, the teeth of the shield 90 are densely arranged at the position P so as to adjust plasma power. Owing to this structure, the density of plasma is not locally increased at the approach region (position P) but can be uniform throughout the inside of the plasma chamber 76.

An activated species of the activated process gas is blown into the process chamber 52 through the injection holes 80 of the barrier wall 78. In this way, the activated species can be blown to the wafers 32 corresponding to the injection holes 80 for bringing the activated species into contact with the wafers 32, so that the wafers 32 held at the boat 34 can make contact with the activated species uniformly along the entire length of the boat 34. In addition, since the boat 34 is rotated by the rotation shaft 64, the in-surface contact distribution of the activated species can uniform for each wafer 32.

In this way, the wafers 32 can be uniformly processed.

If the wafers 32 are completely processed after a preset time, supply of the process gas, rotation of the rotation shaft 64, power supply from the high-frequency power sources 88, heating by the heater 56, and exhausting by the exhaust device are stopped. Thereafter, the wafers 32 are carried from the boat 34 to the cassette 14 placed on the transfer shelf 24 in the reverse order. The cassette 14 is carried from the transfer shelf 24 to the cassette stage 16 by the transfer machine 20, and then the cassette 14 is carried to the outside of the case 12 by the external carrying device (not shown).

In addition, when the boat 34 is in a down position, the bottom side of the process furnace 30 is closed by the furnace port shutter 48 so as to permeation of external air into the process furnace 30.

### Second Embodiment

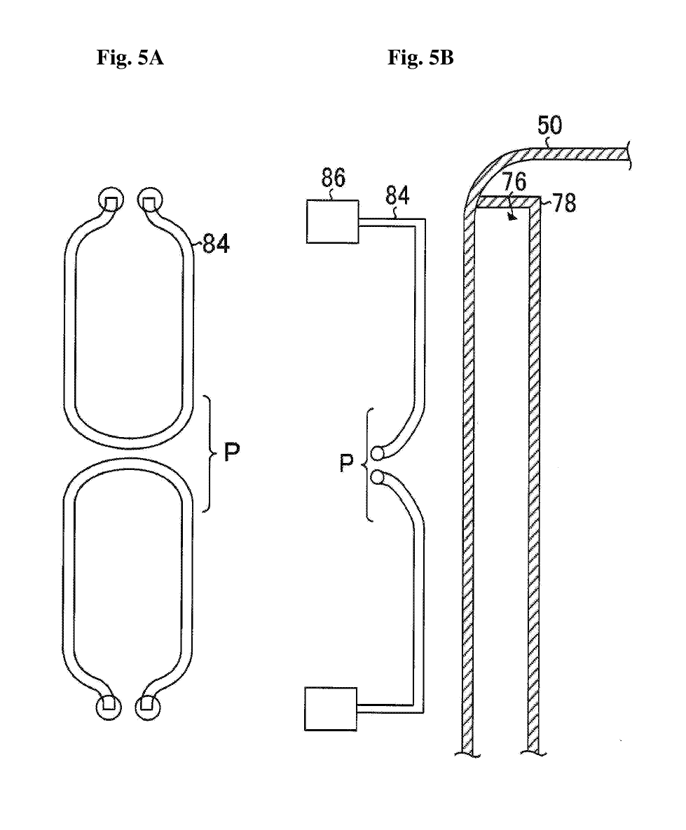

FIG. 5A and FIG. 5B are views illustrating the peripheral structure of high-frequency antennas 84 according to another embodiment of the present invention. FIG. 5A is a schematic front view illustrating the high-frequency antennas 84, and FIG. 5B is a side view illustrating the peripheral structure of the high-frequency antennas 84. In FIG. 5A and FIG. 5B, a shield 90 is not illustrated. In the current embodiment, at an approach region (position P) of the two high-frequency antennas 84, the high-frequency antennas 84 are bent away from a plasma chamber 76 into an arc-shape.

Owing to this structure, the high-frequency antennas 84 can be spaced away from the plasma chamber 76 at the approach region (position P) so as to adjust plasma power. Therefore, the density of plasma is not locally increased at the approach region (position P) but can be uniform throughout the inside of the plasma chamber 76.

### Third Embodiment

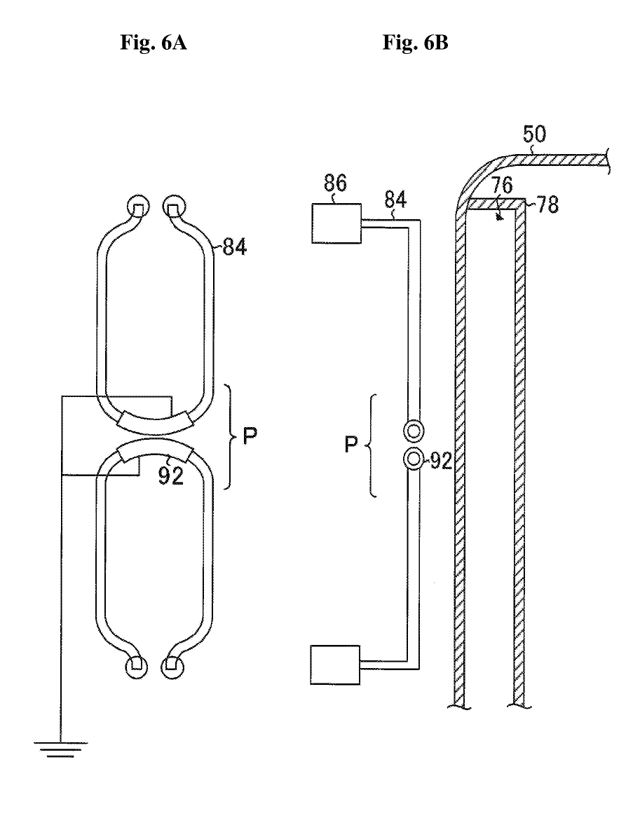

FIG. 6A and FIG. 6B are views illustrating the peripheral structure of high-frequency antennas according to another embodiment of the present invention. FIG. 6A is a schematic front view illustrating the high-frequency antennas 84, and FIG. 6B is a side view illustrating the peripheral structure of the high-frequency antennas 84. In FIG. 6A and FIG. 6B, a shield 90 is not illustrated. According to the current embodiment, at an approach region (position P) of the two high-frequency antennas 84, antenna shields 92 are installed on the high-frequency antennas 84. For example, the antenna shields 92 may be cylindrical or spiral conductors which are independently earthed and provided on the high-frequency antennas 84 with insulators being disposed therebetween. Alternatively, the antenna shields 92 may be earthed to the shield 90.

Owing to this structure, shielding ability can be increased at the approach region (position P), so that plasma power can be adjusted. Therefore, the density of plasma is not locally increased at the approach region (position P) but can be uniform throughout the inside of the plasma chamber 76.

According to the present invention, high-density ICP can be generated uniformly in a vertical direction, and since plasma is generated using low-voltage antennas and a shield is used for voltage cutting, sputtering of parts such as a part made of quartz can be prevented.

The present invention can be used alone as a high-density, sputterless plasma source, and moreover, the present invention can be applied to high-density electron sources of electron beam excited plasma (EBEP) type.

As described above, the present invention provides a semiconductor manufacturing apparatus in which the density of plasma can be uniformly kept in a reaction chamber.

(Supplementary Note)

The present invention also includes the following embodiments.

(Supplementary Note 1)

According to an embodiment of the present invention, there is provided a semiconductor manufacturing apparatus comprising: a process chamber configured to process a substrate; a plurality of electrodes installed outside the process chamber for generating plasma; and an adjusting unit disposed between the process chamber and the electrodes for adjusting density of plasma generating in the process chamber.

(Supplementary Note 2)

In the semiconductor manufacturing apparatus of Supplementary Note 1, the adjusting unit may comprise a shield, and the density of the plasma may be adjusted according to disposition or shape of the shield.

(Supplementary Note 3)

In the semiconductor manufacturing apparatus of Supplementary Note 1, the density of the plasma may be adjusted according to shapes of the electrodes.

What is claimed is:

1. A semiconductor manufacturing apparatus comprising:
a process chamber configured to process a substrate;
a plurality of electrodes installed outside the process chamber for generating plasma; and
an adjusting unit disposed between the process chamber and the electrodes for adjusting density of plasma generating in the process chamber.

2. The semiconductor manufacturing apparatus of claim 1, wherein the adjusting unit comprises a shield, and the density of the plasma is adjusted according to disposition or shape of the shield.

3. The semiconductor manufacturing apparatus of claim 1, wherein the density of the plasma is adjusted according to shapes of the electrodes.
